(19) United States
(12) Patent Application Publication
(10) Pub. No.: US 2026/0188932 A1
(43) Pub. Date: Jul. 2, 2026

(54) SELF-CENTERING ELECTRICAL CONTACTS

(71) Applicant: Raytheon Company, Arlington, VA (US)

(72) Inventors: Michael J. Pereira, Providence, RI (US); Dennis W. Mercier, Hudson, MA (US); Nicholas C. Defilipp, Melrose, MA (US)

(21) Appl. No.: 19/431,688

(22) Filed: Dec. 23, 2025

Related U.S. Application Data
(60) Provisional application No. 63/739,024, filed on Dec. 26, 2024.

(51) Int. Cl. H01R 12/91; H01R 12/73; H01R 43/02

(52) U.S. Cl. CPC H01R 12/91; H01R 12/73; H01R 43/0256

(57) ABSTRACT

A self-centering electrical connector for electronics components includes a pin and a circuit board. The pin includes an elongate connector portion having a first end and a second end, a first electrical contact formed at the second end, and a first mask positioned against the second end, the first mask configured to divide the first electrical contact into a first plurality of regions. The circuit board includes a second electrical contact, and a second mask disposed on the second electrical contact, the second mask configured to divide the second electrical contact into a second plurality of regions. The first mask and the second mask are configured to mate to form a plurality of soldering regions between first plurality of regions and the second plurality of regions.

### CLAIM OF PRIORITY

This patent application claims the benefit of priority to U.S. Provisional Application Ser. No. 63/739,024, filed Dec. 26, 2024, which is incorporated by reference herein in its entirety.

### TECHNICAL FIELD

The present disclosure is generally directed to, but not by way of limitation, connectors for coupling components in electrical systems, such as electronics components. More specifically, the present disclosure relates to, but not by way of limitation, systems, devices and methods for precisely placing electrical connectors to facilitate alignment with other electrical connectors.

### BACKGROUND

Electrical components can take various forms. For example, electrical components can comprise power components, such as batteries, AC-DC converters, transformers and the like, communications devices, integrated circuits, processing components, memory components and others. Electrical components can be used in many contexts, including personal computers, mobile computing devices, automobiles, telecommunications devices, defense systems and the like. In some contexts, electrical components must take on compact form factors or form factors having irregular shapes. For example, many electrical components are used in aerospace applications where size and space are at a premium. In particular, satellites, rockets, and electric vehicles typically require electronics to be small and lightweight. Furthermore, electronics components in such applications are frequently stacked on top of each other to fit within elongate packages.

### SUMMARY

In an example, a self-centering electrical connector for electronics components comprises a pin and a circuit board. The pin comprises an elongate connector portion comprising a first end and a second end, a first electrical contact formed at the second end, and a first mask positioned against the second end, the first mask configured to divide the first electrical contact into a first plurality of regions. The circuit board comprises a second electrical contact, and a second mask disposed on the second electrical contact, the second mask configured to divide the second electrical contact into a second plurality of regions. The first mask and the second mask are configured to mate to form a plurality of soldering regions between first plurality of regions and the second plurality of regions.

In another example, a method of joining electrical components with a self-centering electrical contact comprises positioning a soldering mask between a first electrical connector and a second electrical connector, dividing soldering material into a plurality of regions with the soldering mask, allowing surface tensions in the soldering material within the plurality of regions to self-center the first electrical connector on the second electrical connector, and solidifying the soldering material.

### BRIEF DESCRIPTION OF THE DRAWINGS

FIG. 1 is a schematic, cross-sectional, exploded view of a device in which an electronics system having stacked electronics components is disposed.

FIG. 2A is an exploded perspective view of a first electrical component comprising a socket connector and a second electrical component having a plurality of surface mount pins.

FIG. 2B is a schematic assembled view of the first electrical component and the second electrical component of FIG. 2A showing a plurality of pin receptacles.

FIG. 3 is a perspective view of a surface mount pin connected to a circuit board using a self-centering pin coupler of the present application.

FIG. 4 is a perspective view of the surface mount pin of FIG. 3 exploded from the circuit board to show soldering material located therebetween.

FIG. 5 is a perspective view of the surface mount pin of FIG. 3 and FIG. 4 showing a soldering mask disposed on a bottom surface of a pedestal of the surface mount pin.

FIG. 6 is a perspective, cross-sectional view of the circuit board of FIG. 3 and FIG. 4 showing a soldering mask connected to an electrical contact.

FIG. 7 is a cross-sectional view of the surface mount pin of FIG. 3 connected to the circuit board to show engagement of the soldering masks.

FIG. 8 is a bottom view of a circular pedestal of a surface mount pin showing a soldering mask forming four quadrants.

FIG. 9 is a bottom view of a square pedestal of a surface mount pin showing a soldering mask forming four quadrants.

FIG. 10 is a bottom view of a circular pedestal of a surface mount pin showing a soldering mask forming two sectors.

FIG. 11 is a bottom view of a circular pedestal of a surface mount pin showing a soldering mask forming concentric sectors.

FIG. 12 is a schematic view of an imaging system for placing a surface mount pin on a circuit board so that the soldering mask of the surface mount pin aligns with the soldering mask of the circuit board.

FIG. 13 is a block diagram of methods for placing and joining a surface mount pin with a contact surface of a circuit board.

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

### DETAILED DESCRIPTION

The present inventors have recognized, among other things, that problems to be solved in electrical connectors relate to aligning electrical connectors in stacked arrangements. In particular, it can be difficult to align pin connectors with their associated sockets. For example, sometimes pin connectors are aligned in rows and are intended to be inserted into an associated row of sockets. As such, it is desirable for the pins to be properly placed to align with the sockets so that the pins are inserted straight into the sockets. Misalignment of the pins with the sockets can result in the pins bending or flexing to be inserted into the sockets. Bending and flexing of the pins can induce undesirable stress or even breakage of the pins. In some applications, pins are mounted to their associated circuit board via surface mount connections where each pin is individually placed on the circuit board to form an electrical connection therewith, such as with a soldered connection. A contact surface of each pin is placed into alignment with a corresponding contact surface of the circuit board so that a connection can be formed therebetween. A small volume of soldering material can be placed between the contact surfaces to join the two components. However, due to surface tension in the soldering material, it is possible for the contact surface of the pin to be drawn slightly off-center of the contact surface of the circuit board. Thus, there is potential for misalignment of only a few pins or even one pin interfering with insertion of the row of pins into the row of sockets.

The present subject matter can help provide solutions to these problems and other problems, such as by providing a self-centering contact for an electrical connector. An electrical connection between a pin and a circuit board can include a soldering mask that divides soldering material into two or more volumes. As such, surface tension generated in each volume is smaller than if a single large volume of soldering material were used. Furthermore, the separate volumes of soldering material can generate competing surface tension forces that can have a tendency to self-center the pin on the circuit board. In examples, the soldering mask can produce wedge-shaped soldering volumes on circular contact surface, concentric soldering volumes on circular contact surface, quadrant-shaped soldering volumes on rectilinear or circular contact surfaces, and the like. In examples, a soldering mask is placed on, e.g., attached to, each contact surface of the pin and the circuit board. The soldering masks can be aligned or mated to facilitate the formation of sub-divided soldering volumes that can generate equal or nearly-equal surface tension forces in each divided volume.

This overview is intended to provide an overview of subject matter of the present patent application. It is not intended to provide an exclusive or exhaustive explanation of the disclosure. The detailed description is included to provide further information about the present patent application.

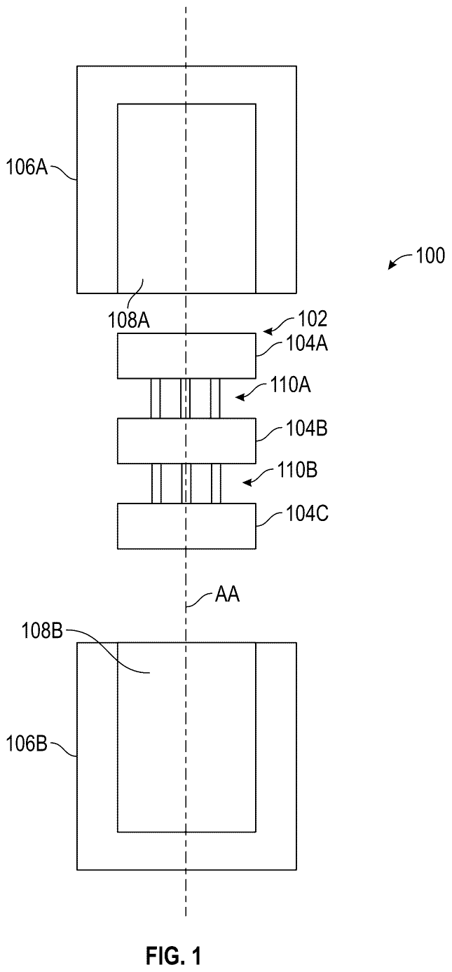

FIG. 1 is a schematic, cross-sectional, exploded view of device 100 in which electronics system 102 having first electronics component 104A, second electronics component 104B and third electronics component 104C are disposed. Device 100 can comprise upper container 106A and lower container 106B. Upper container 106A can include upper cavity 108A and lower container 106B can contain lower cavity 108B. Electronics system 102 can include connectors 110A and connectors 110B.

Device 100 can comprise a system including electronics components. In examples, device 100 can comprise a satellite body or a rocket casing having a shape configured for aerospace applications. In additional examples, device 100 can comprise a portion of an electric vehicle. As such, it can be desirable for device 100 to have an elongate shape along axis AA. As such, it may not always be possible for a single circuit board to be constructed to receive all of the desired electronics components. As such, first electronics component 104A through third electronics component 104C are stacked to fit within upper cavity 108A and lower cavity 108B. As such, it is desirable for connectors 110A and connectors 110B to facilitate vertical stacking of first electronics component 104A through third electronics component 104C. With the present disclosure, connectors 110A and connectors 110B can include self-centering electrical contacts on one electrical component that are precisely placed to align with mating electrical connectors of an opposite electrical component.

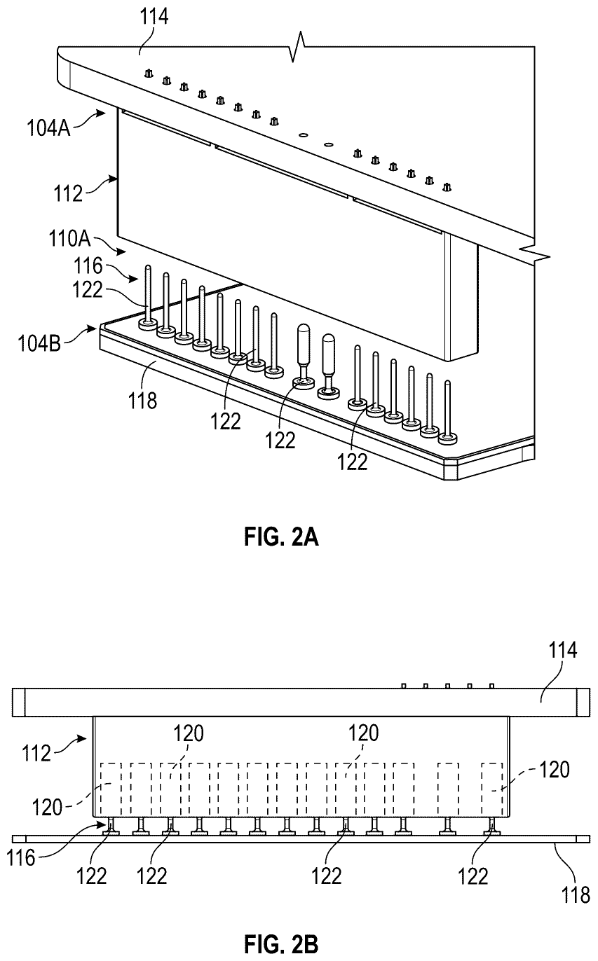

FIG. 2A is an exploded perspective view of first electronics component 104A and second electronics component 104B of FIG. 1 connected by connectors 110A. FIG. 2B is a schematic assembled view of first electronics component 104A and second electronics component 104B of FIG. 2A showing socket block 112 engaged with pin block 116. FIG. 2A and FIG. 2B are discussed concurrently.

First electronics component 104A can comprise socket block 112 extending from first circuit board 114. Second electronics component 104B can comprise pin block 116 extending from second circuit board 118. Socket block 112 can include a plurality of sockets, e.g., sockets 120. Pin block 116 can include a plurality of pins, e.g., pins 122.

Pins of pin block 116 can be disposed along second circuit board 118 in any arrangement. In the illustrated example, the pins of pin block 116 are arranged in a row having various intervals between pins. As such, socket block 112 can include sockets arranged in a row having the same intervals as the pins. The interval between the pins and sockets is predetermined based on the designs of the electrical components attached to first circuit board 114 and second circuit board 118. Thus, it is important for the pins of pin block 116 to extend from second circuit board 118 and the sockets of socket block 112 to be located within socket block 112 at the predetermined interval to facilitate alignment and assembly. Second circuit board 118 can be manufactured to include contact surfaces for the pins of pin block 116. Second circuit board 118 can be manufactured with contact surfaces in precise locations to align with sockets of socket block 112. However, in examples, pins of pin block 116 can be subsequently placed on the contact surfaces of second circuit board 118, thereby introducing another potential source of misalignment between pin block 116 and socket block 112. The present disclosure provides surface-mount pin connector assemblies and methods for attaching pin connectors to circuit boards that allow for precise placement and joining of the pin connectors on contact surfaces of the circuit board. In particular, pins of pin block 116 can be placed onto contact surfaces of second circuit board 118 using self-centering connectors that, among other things, divide surface tension forces of soldering material to prevent drifting of the pins away from centers of the contact surfaces.

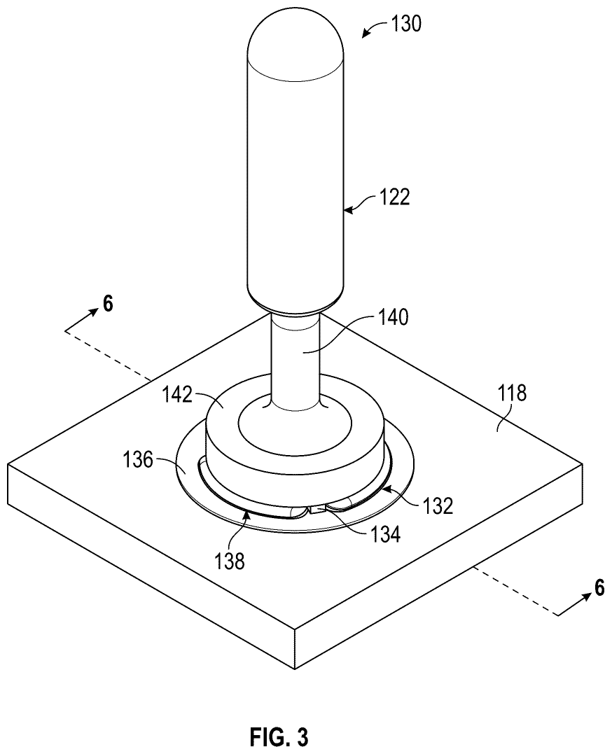

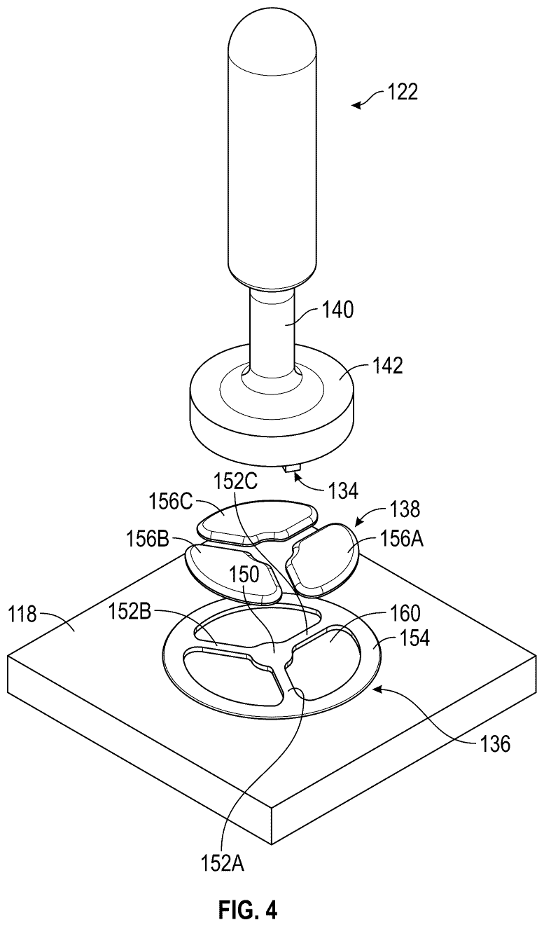

FIG. 3 is a perspective view of self-centering pin assembly 130 comprising pin 122 connected to second circuit board 118 using self-centering pin coupler 132 of the present application. Self-centering pin coupler 132 can comprise pin mask 134, board mask 136 and soldering material 138. Pin 122 can be configured to conduct electrical current to or from electrical contact 160 (FIG. 4) of second circuit board 118. In examples, pin 122 and electrical contact 160 can be fabricated from conducting material, such as copper. Pin mask 134 can be located on the bottom of pin 122 and board mask 136 can be located on the top of electrical contact 160 (FIG. 4). Pin mask 134 and board mask 136 can be mated to form pockets, sectors or sections for receiving soldering material 138. The pockets of soldering material 138 can be separated from each other to divide the solder material into smaller volumes than the total volume of solder material used. As such, surface tension forces created by the soldering material in liquid form can be split to form surface tension vectors that are in opposition to each other to cause self-centering of pin 122.

FIG. 4 is a perspective view of self-centering pin assembly 130 of FIG. 3 showing pin 122 exploded from second circuit board 118 to show soldering material 138 located therebetween. FIG. 5 is a perspective view of pin 122 of FIG. 3 and FIG. 4 showing pin mask 134 disposed on bottom surface 144 of pedestal 142. FIG. 4 and FIG. 5 are discussed concurrently.

As shown in FIG. 5, pin 122 can comprise shaft 140 and pedestal 142 having bottom surface 144. A proximal tip of shaft 140 can comprise a first end of pin 122 and bottom surface 144 can comprise a second end of pin 122. Pedestal 142 can form a widened portion of pin 122 that allows for bonding of pin 122 with electrical contact 160. Pin mask 134 can comprise hub 146, first spoke 148A, second spoke 148B and third spoke 148C. As shown in FIG. 4, board mask 136 can comprise hub 150, first spoke 152A, second spoke 152B, third spoke 152C and rim 154. Soldering material 138 can comprise first portion 156A, second portion 156B and third portion 156C. Second circuit board 118 can comprise electrical contact 160.

Pin 122 can comprise a monolithic body of conducting material, such that pedestal 142 and shaft as copper. In examples, pedestal 142 can have a circular cross-sectional profile and electrical contact 160 can have a mating cross-sectional shape. However, pedestal 142 can have other shapes, such as square, rectangular, hexagonal and octagonal. As mentioned, electrical current can be passed between bottom surface 144 of pin 122 and the top surface of electrical contact 160 when bottom surface 144 is in opposition to electrical contact 160. Pin mask 134 can be placed on bottom surface 144 and board mask 136 can be placed on electrical contact 160 to influence the shape of soldering material (FIG. 4) placed between pin 122 and electrical contact 160. Pin mask 134 and board mask 136 can be fabricated from any suitable material for forming a soldering mask as is known in the art, such as those that can adhere to conducting surfaces, are conducting and can survive a soldering process. In examples, pin mask 134 and board mask 136 can be fabricated from a polymer or an epoxy.

In the illustrated example of FIG. 4 and FIG. 5, pin mask 134 and board mask 136 can have a wagon wheel shape wherein soldering material 138 can be divided into pie-piece-shaped or wedge-shaped pockets. In examples, three pockets are formed by first spoke 148A through third spoke 148C and first spoke 152A through third spoke 152C. However, fewer or greater numbers of spokes can be used in other embodiments. For example, two spokes (e.g., FIG. 10), four spokes (e.g., FIG. 8), five spokes or more can be used. Hub 146 can be located at the center of bottom surface 144. First spoke 148A through third spoke 148C can extend radially outward from hub 146. First spoke 148A through third spoke 148C can be spaced at even intervals. For example, the angular spacing between spokes can be even such that for the example of FIG. 5, each spoke can be separated by approximately one-hundred-twenty degrees. Such equal interval spacing can facilitate surface tension forces in soldering material within each pocket being roughly equal. However, in other examples, the spacing intervals can be uneven.

First spoke 152A through third spoke 152C can be spaced at intervals equal to those of first spoke 148A through third spoke 148C. Thus, the angular spacing between each of first spoke 152A, second spoke 152B and third spoke 152C can be approximately one-hundred-twenty degrees. As such, first spoke 148A through third spoke 148C can be engaged flush with first spoke 152A through third spoke 152C, respectively. In examples, the widths of first spoke 148A through third spoke 148C can be equal to the widths of first spoke 152A through third spoke 152C. However, in examples the widths of first spoke 148A through third spoke 148C can be different than the widths of first spoke 152A through third spoke 152C. Hub 150 can be located at the center of electrical contact 160. First spoke 152A through third spoke 152C can extend radially outward from hub 150. First spoke 152A through third spoke 152C can be surrounded by rim 154. Rim 154 can contain soldering material 138 between first spoke 152A through third spoke 152C.

A pocket can be formed between first spoke 148A and second spoke 148B, a pocket can be formed between second spoke 148B and third spoke 148C, and a pocket can be formed between third spoke 148C and first spoke 148A. Likewise, a pocket can be formed between first spoke 152A and second spoke 152B, a pocket can be formed between second spoke 152B and third spoke 152C, and a pocket can be formed between third spoke 152C and first spoke 152A. The pockets formed by board mask 136 and pin mask 134 can be equally sized as discussed herein. As such, soldering material 138 can be placed in the pockets such that first portion 156A, second portion 156B and third portion 156C are formed, as shown in FIG. 4.

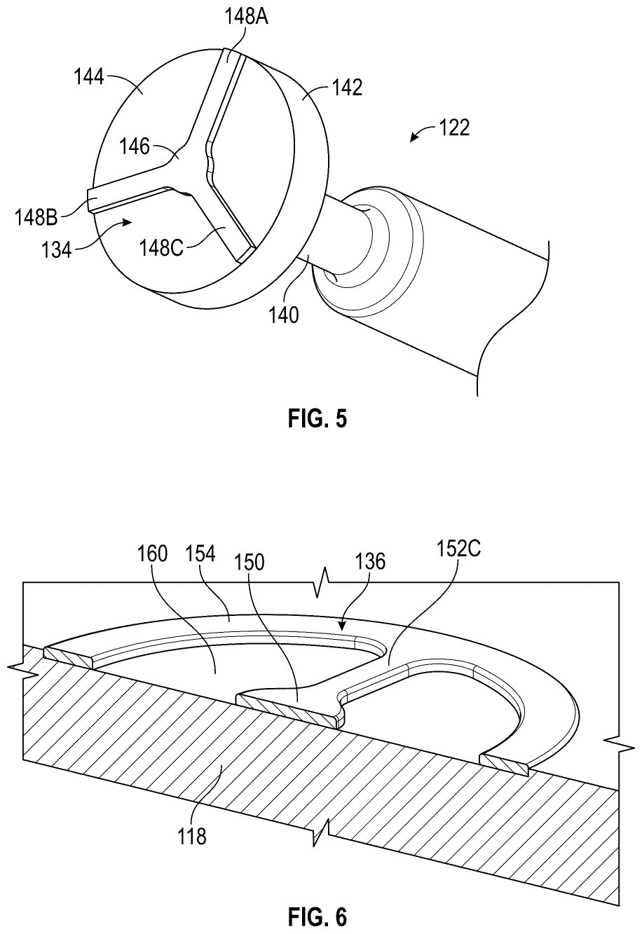

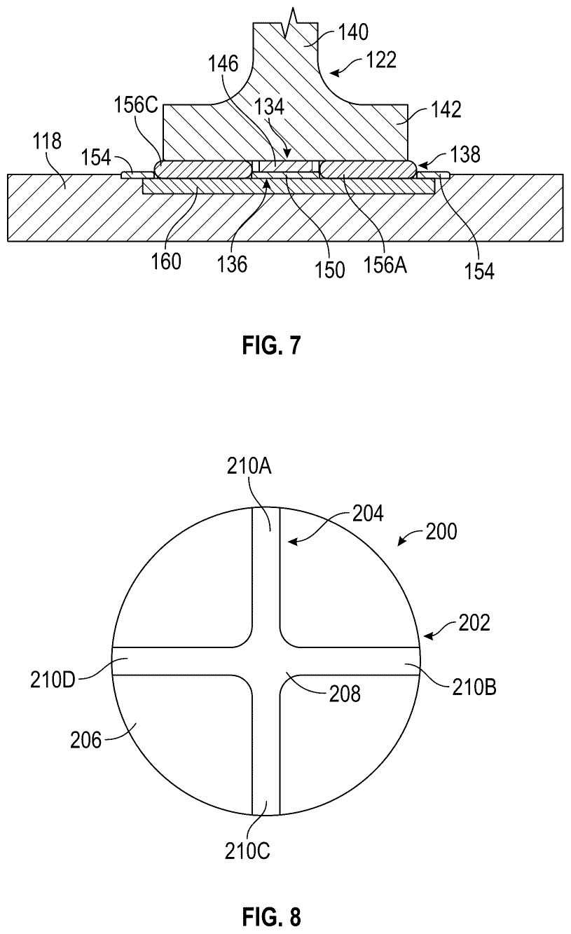

FIG. 6 is a perspective, cross-sectional view of circuit board of FIG. 3 and FIG. 4 showing board mask 136 connected to electrical contact 160. FIG. 7 is a cross-sectional view of pin 122 of FIG. 3 and second circuit board 118 showing soldering material 138 within pin mask 134 and board mask 136. FIG. 6 and FIG. 7 are discussed concurrently.

Pin mask 134 can be placed on top of board mask 136 to that hub 146 engages flush with hub 150. As can be seen in FIG. 6, board mask 136 can have a thickness such that board mask 136 rises above electrical contact 160. In examples, the thickness of board mask 136 can be in the range of approximately 0.2 mil (˜0.00508 millimeter) to approximately 1.6 mil (˜0.04064 millimeter). However, greater thicknesses can be used. In examples, pin mask 134 can have a thickness equal to the thickness of board mask 136. However, in examples, pin mask 134 and board mask 136 can have different thicknesses. In the illustrated example, pin mask 134 is thicker than board mask 136. The illustrated example shows a soldering mask be placed on each of pin 122 and electrical contact 160. However, in other examples, only one soldering mask can be used on either of pin 122 or electrical contact 160. As discussed, pin mask 134 and board mask 136 can mate to form two halves of a thicker soldering mask. Thus, three pockets can be formed by pin mask 134 and board mask 136 for the illustrated example.

Third portion 156C of soldering material 138 and first portion 156A of soldering material 138 can be positioned between pin 122 and electrical contact 160. Surface tension can be generated in third portion 156C that pushes pin 122 radially outward away from hub 150. Likewise, surface tension can be generated in first portion 156A (FIG. 4) that pushes pin 122 radially outward away from hub 150. Surface tension within first portion 156A and third portion 156C can cancel each other out, thereby centering pin 122 on electrical contact 160. As discussed, with soldering material 138 being broken into three separate volumes or pools of material, the total force from surface tension is also broken into smaller forces. These smaller surface tension forces can act against each other to reduce the chances of pin 122 being moved off center from electrical contact 160. Ideally, the smaller surface tension forces would cancel each other out to allow pin 122 to self-center on electrical contact 160. However, even if the three smaller surface tension forces do not completely cancel each other out, the random nature of where each surface tension force could be pointing will reduce the overall resulting sum of the forces from being able to push pin 122 in any one direction a significant amount.

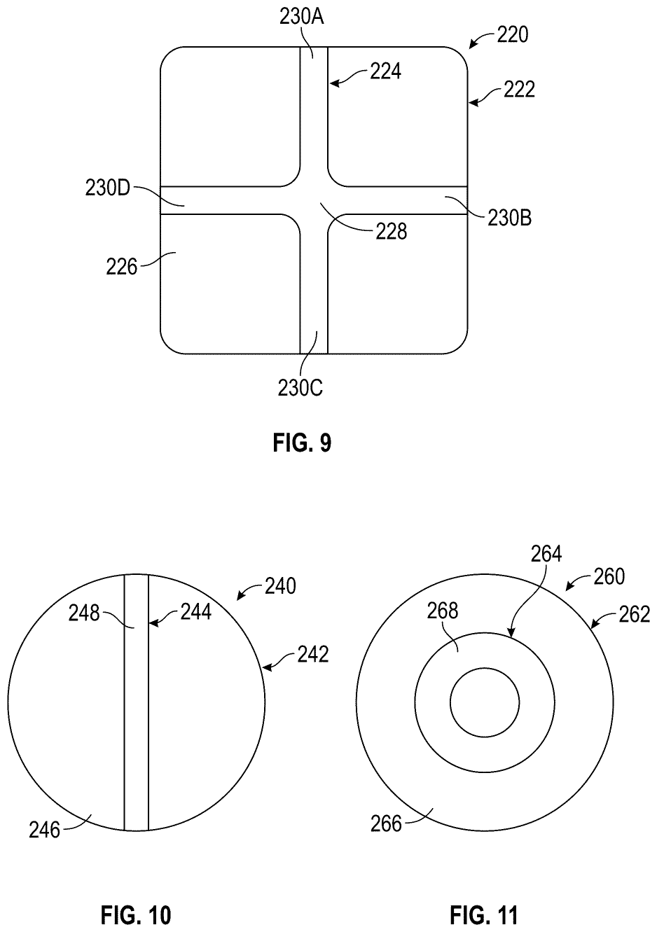

Although FIG. 3 through FIG. 7 are shown with a particular example of a three-spoke soldering mask, other configurations of soldering masks can be used, as discussed with reference to FIG. 9 through FIG. 11.

FIG. 8 is a bottom view of surface mount pin 200 comprising pedestal 202 having a circular cross-sectional profile and having soldering mask 204 forming pockets having four quadrants. Pedestal 202 can have bottom surface 206 against which soldering mask 204 is engaged. Soldering mask 204 can comprise hub 208, first spoke 210A, second spoke 210B, third spoke 210C and fourth spoke 210D.

Surface mount pin 200 can be configured similarly as pin 122. Soldering mask 204 can be configured similarly as pin mask 134 except soldering mask 204 can include four spokes instead of three. Soldering mask 204 can produce four pockets or regions for soldering material 138 that are pie-shaped or wedge-shaped. In examples, the angular spacing between first spoke 210A through fourth spoke 210D can be even such that for the example of FIG. 8, each spoke can be separated by approximately ninety degrees. Thus, soldering material within each region can produce surface tensions that can have a tendency to cancel each other out.

FIG. 9 is a bottom view of surface mount pin 220 comprising pedestal 222 having a square cross-sectional profile and having soldering mask 224 forming pockets having four quadrants. Pedestal 222 can have bottom surface 226 against which soldering mask 224 is engaged. Soldering mask 224 can comprise hub 228, first spoke 230A, second spoke 230B, third spoke 230C and fourth spoke 230D.

Surface mount pin 220 can be configured similarly as surface mount pin 220. However, pedestal 222 can be square instead of round like pedestal 202. Soldering mask 224 can be configured similarly as soldering mask 204. Soldering mask 224 can produce four regions for soldering material 138 that are quadrant-shaped of square-shaped. For example, the angular spacing between spokes can be even such that for the example of FIG. 5, each spoke can be separated by approximately ninety degrees. Thus, soldering material within each region can produce surface tensions that can have a tendency to cancel each other out.

FIG. 10 is a bottom view of surface mount pin 240 comprising pedestal 242 having a circular cross-sectional profile and having soldering mask 244 forming two pockets, regions or sectors. Pedestal 242 can have bottom surface 246 against which soldering mask 244 is engaged. Soldering mask 244 can comprise rail 248.

Surface mount pin 240 can be configured similarly as pin 122. Soldering mask 244 can divide bottom surface 246 into two regions. In examples, soldering mask 244 can comprise a rail or a combination of two spokes disposed end-to-end. Soldering mask 244 can produce two regions for soldering material 138 that are semi-circular shaped. Thus, soldering material within each region can produce surface tensions that can have a tendency to cancel each other out.

FIG. 11 is a bottom view of surface mount pin 260 comprising pedestal 262 having a circular cross-sectional profile and having soldering mask 264 forming two concentric pockets, regions or sectors. Pedestal 262 can have bottom surface 266 against which soldering mask 264 is engaged. Soldering mask 264 can comprise ring 268.

Surface mount pin 260 can be configured similarly as pin 122. Soldering mask 264 can divide bottom surface 246 into two regions. In examples, soldering mask 264 can comprise a ring-shaped body, such as a circle. In additional examples, other shapes can be used, such as oval or square shaped. Additionally, though FIG. 11 shows a single ring, multiple rings can be used. Soldering mask 264 can produce two regions for soldering material 138 that are annularly shaped. Thus, soldering material within each region can produce surface tensions that can have a tendency to cancel each other out.

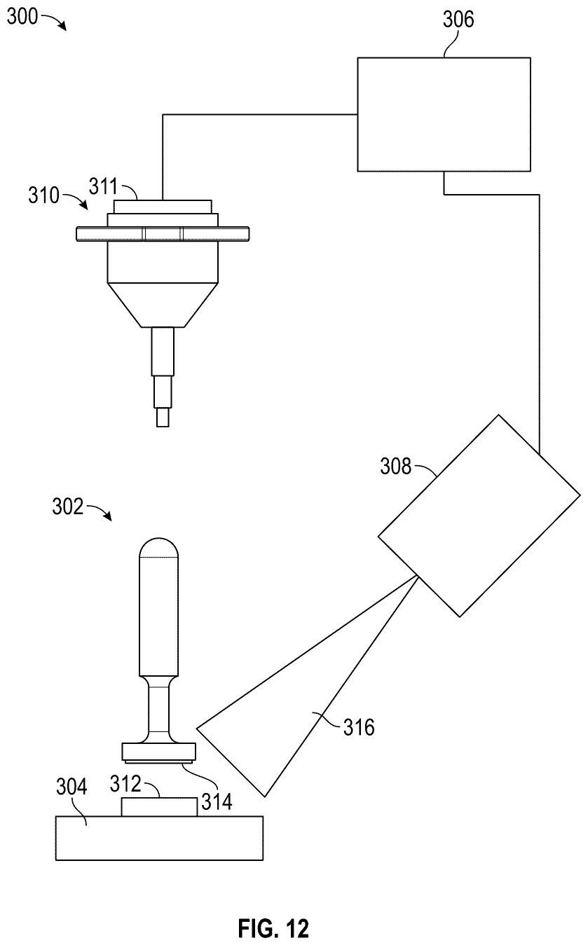

FIG. 12 is a schematic view of placement system 300 for placing surface mount pin 302 on circuit board 304. Placement system 300 can comprise controller 306, camera 308 and placement head 310. Placement head 310 can be connected to an articulating arm, such as a robotic arm, via swivel joint 311. Circuit board 304 can comprise soldering mask 312. Surface mount pin 302 can comprise soldering mask 314. Soldering mask 312 and soldering mask 314 can comprise any of the soldering masks described herein. Camera 308 can emit beam 316. Placement system 300 can be configured to position surface mount pin 302 on circuit board 304 so that soldering mask 314 of surface mount pin 302 aligns with soldering mask 312 of circuit board 304. Placement system 300 can include other sub-systems, such as suction systems for applying suction to placement head 310, a conveyor system for moving instances of surface mount pin 302 relative to placement head 310 and circuit board 304, which are not illustrated for simplicity. Placement system 300 can comprise a “pick and place” system or machine as commonly known.

During operation a conveyor system can move surface mount pin 302 into close proximity of circuit board 304. A robotic arm can move placement head 310 into engagement with surface mount pin 302. Suction can be applied to surface mount pin 302 to lift surface mount pin 302. Camera 308 can emit beam 316 to scan surface mount pin 302 including soldering mask 314. Controller 306 can receive imaging signals from camera 308 to determine the shape of soldering mask 314. Likewise, camera 308 can emit beam 316 to scan circuit board 304 including soldering mask 312. Controller 306 can receive imaging signals from camera 308 to determine the shape of soldering mask 312. The robotic arm connected to placement head 310 can move surface mount pin 302 into axial alignment with soldering mask 312. Controller 306 can activate swivel joint 311 to rotate surface mount pin 302 to align the shape of soldering mask 314 with the shape of soldering mask 312. Soldering material can be placed between soldering mask 312 and soldering mask 314, such as by being placed in the various pockets, regions or sectors formed in the soldering mask as described herein. The soldering material can be placed in a heated or liquid state. The robotic arm can move placement head 310 downward so that soldering mask 314 contacts soldering mask 312. Thereafter, soldering material placed between soldering mask 312 and soldering mask 314 can be solidified, such as by being cooled after penetrating into the material of surface mount pin 302 and circuit board 304, to bond surface mount pin 302 to circuit board 304. In examples, the solder material can comprise tin-based alloys that are commonly used in soldering processes.

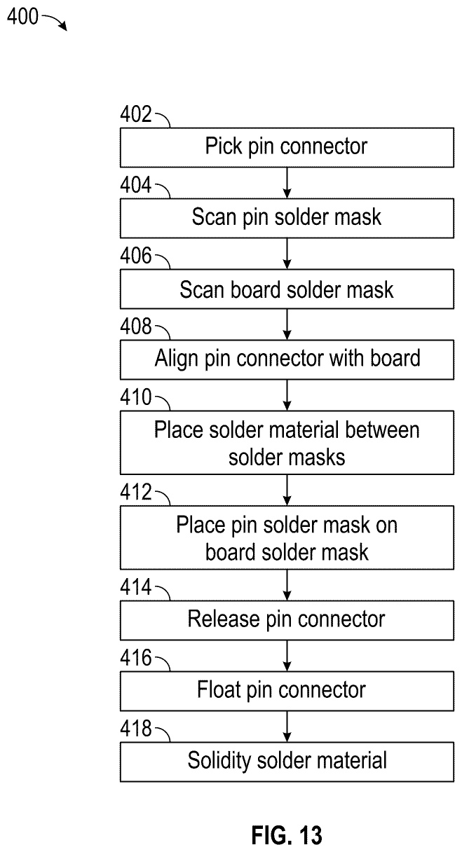

FIG. 13 is a block diagram illustrating method 400 including operation 402 through operation 418 for placing and joining a surface mount pin with a contact surface of a circuit board. Though discussed with reference to FIG. 1 through FIG. 12 and particular examples of self-centering electrical contacts, method 400 can encompass the use of any self-centering electrical contact consistent with the methods and systems described herein. Method 400 can additionally include fewer or greater operations other than operation 402 to operation 418. Additionally, in other examples, operation 402 through operation 418 can be performed in other sequences.

At operation 402, surface mount pin 302 can be grasped with placement head 310. In examples, placement head 310 can apply suction to shaft 140 of surface mount pin 302 to attach to, e.g., grasp, surface mount pin 302. Surface mount pin 302 can be moved into proximity of camera 308 so that soldering mask 314 can be viewed.

At operation 404, surface mount pin 302 can be scanned with camera 308 to obtain imaging of soldering mask 314. Beam 316 can be used to discern the shape and orientation of soldering mask 314 by controller 306.

At operation 406, circuit board 304 can be scanned with camera 308 to obtain imaging of soldering mask 312. Beam 316 can be used to discern the shape and orientation of soldering mask 312 by controller 306.

At operation 408, soldering mask 314 can be aligned with board mask. Controller 306 can receive imaging of one or both of soldering mask 314 and soldering mask 312 and determine the shapes thereof and the relative rotations thereof. Placement head 310 can axially align surface mount pin 302 with soldering mask 312 so as to be perpendicular thereto. Placement head 310 can rotate surface mount pin 302 to align soldering mask 314 with soldering mask 312 such that spokes of each component can be circumferentially aligned. Controller 306 can activate swivel joint 311 to rotate surface mount pin 302.

At operation 410, soldering material 138 can be placed between soldering mask 314 and soldering mask 312. In examples, soldering material 138 can be placed on an electrical contact of circuit board 304 underneath soldering mask 312 in regions defined by soldering mask 312. The spokes or shapes of each of soldering mask 312 and soldering mask 314 can divide the soldering material into discrete, smaller volumes. In examples, the smaller volumes can be equal in volume.

At operation 412, surface mount pin 302 can be advanced toward circuit board 304 to move soldering mask 314 into engagement with soldering mask 312. Placement head 310 can hold surface mount pin 302 so that soldering mask 314 is parallel to soldering mask 312. Placement head 310 can advance surface mount pin 304 so that soldering mask 314 is engaged flush with soldering mask 312.

At operation 414, surface mount pin 302 can be released by placement head 310. Placement head 310 can release suction from surface mount pin 302 and the robotic arm can move placement head 310 out of contact with surface mount pin 302.

At operation 416, surface mount pin 302 can be floated on soldering material 138. That is, surface tension of soldering material 138 can cause surface mount pin 302 to momentarily float when released by placement head 301. Surface tension forces within first portion 156A, second portion 156B and third portion 156C of soldering material 138 can act on surface mount pin 302. However, with the present disclosure, the surface tension forces can cancel each other out, thereby causing surface mount pin 302 to self-center on circuit board 304.

At operation 418, soldering material 138 can be solidified to attach and immobilize surface mount pin 302 on circuit board 304. Soldering material 138 can cool down and harden to bond surface mount pin 302 with circuit board 304. Soldering mask 312 and soldering mask 314 can be held in abutment by the soldered joint.

The above detailed description includes references to the accompanying drawings, which form a part of the detailed description. The drawings show, by way of illustration, specific embodiments in which the disclosure can be practiced. These embodiments are also referred to herein as “examples.” Such examples can include elements in addition to those shown or described. However, the present disclosure also contemplates examples in which only those elements shown or described are provided. Moreover, the present disclosure also contemplates examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, the disclosed subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the disclosure should be determined with reference to the appended claims, along with the full scope of equivalents to which such claims are entitled.

1. A self-centering electrical connector for electronics components, the self-centering electrical connector comprising:
a pin comprising:
an elongate connector portion comprising a first end and a second end;
a first electrical contact formed at the second end; and
a first mask positioned against the second end, the first mask configured to divide the first electrical contact into a first plurality of regions; and
a circuit board comprising:
a second electrical contact; and
a second mask disposed on the second electrical contact, the second mask configured to divide the second electrical contact into a second plurality of regions;
wherein first mask and the second mask are configured to mate to form a plurality of soldering regions between first plurality of regions and the second plurality of regions.

2. The self-centering electrical connector of claim 1, wherein the second end of the elongate connector portion comprises a pedestal forming the first electrical contact on which the first mask is located.

3. The self-centering electrical connector of claim 2, wherein the first electrical contact and the second electrical contact have the same cross-sectional profile.

4. The self-centering electrical connector of claim 3, wherein the first mask comprises:
a first hub located at a center of the first electrical contact; and
a first plurality of spokes extending from the first hub.

5. The self-centering electrical connector of claim 4, wherein the second mask further comprises:
a second hub; and
a second plurality of spokes extending from the second hub.

6. The self-centering electrical connector of claim 5, wherein the second mask is surrounded by a rim connected to ends of the second plurality of spokes.

7. The self-centering electrical connector of claim 1, wherein:
the first mask comprises a first ring dividing the first electrical contact into two regions; and
the second mask comprises a second ring dividing the second electrical contact into two regions.

8. The self-centering electrical connector of claim 1, wherein:
the first mask comprises a first rail dividing the first electrical contact into two regions; and
the second mask comprises a second rail dividing the second electrical contact into two regions.

9. The self-centering electrical connector of claim 1, wherein the first mask is thicker than the second mask.

10. A method of joining electrical components with a self-centering electrical contact, the method comprising:
positioning a soldering mask between a first electrical connector and a second electrical connector;
dividing soldering material into a plurality of regions with the soldering mask;
allowing surface tensions in the soldering material within the plurality of regions to self-center the first electrical connector on the second electrical connector; and
solidifying the soldering material.

11. The method of claim 10, further comprising allowing the first electrical connector to float on the soldering material.

12. The method of claim 11, wherein positioning the soldering mask between the first electrical connector and the second electrical connector comprises positioning a pin mask connected to the pin into engagement with a board mask connected to the circuit board.

13. The method of claim 12, wherein:
the first electrical connector comprises a pin; and
the second electrical connector comprises a circuit board.

14. The method of claim 13, further comprising using a pick and place machine to position the pin relative to the circuit board.

15. The method of claim 14, wherein using the pick and place machine to position the pin relative to the circuit board comprises:
grasping the pin with an articulating arm;
scanning at least one of the pin mask and the board mask;
aligning the pin mask with the board mask; and
placing the pin mask onto the board mask so that the pin mask aligns with the board mask.

16. The method of claim 10, wherein dividing the soldering material into the plurality of regions with the soldering mask comprises dividing the soldering material into a plurality of equally-sized regions.

17. The method of claim 16, wherein dividing the soldering material into the plurality of regions with the soldering mask comprises dividing the soldering material into four quadrants.

18. The method of claim 16, wherein dividing the soldering material into the plurality of regions with the soldering mask comprises dividing the soldering material into equally-sized wedge-shaped regions.

19. A surface mount pin for an electrical connector, the surface mount pin comprising:
a shaft extending from a first end comprising a tip to a second end comprising a base;
a pedestal located at the base, the pedestal comprising a widened portion of the surface mount pin to define an electrical contact surface; and
a soldering mask located on the electrical contact surface, the soldering mask shaped to divide the electrical contact surface into a plurality of equally-sized regions.

20. The surface mount pin of claim 19, wherein the soldering mask comprises:
a hub located at a center of the electrical contact surface; and
a plurality of spokes extending radially outward from the hub.
